(19) United States
(12) Patent Application Publication
(10) Pub. No.: US 2016/0322412 A1
(43) Pub. Date: Nov. 3, 2016

(54) SOLID-STATE IMAGING DEVICE AND IMAGING APPARATUS

(71) Applicant: OLYMPUS CORPORATION, Tokyo (JP)

(72) Inventors: Yusuke Yamamoto, Kawasaki-shi (JP); Shuichi Kato, Tokyo (JP)

(73) Assignee: OLYMPUS CORPORATION, Tokyo (JP)

(21) Appl. No.: 15/206,696

(22) Filed: Jul. 11, 2016

Related U.S. Application Data
(63) Continuation of application No. PCT/JP2015/053203, filed on Feb. 5, 2015.

(30) Foreign Application Priority Data
Feb. 5, 2014 (JP) 2014-020479

(51) Int. Cl. H01L 27/146; G02B 3/00; H04N 5/369

(52) U.S. Cl. CPC H01L 27/14627; H04N 5/3696; G02B 3/0056; H01L 27/14621; H01L 27/14623; H01L 27/14629

(57) ABSTRACT

A solid-state imaging device includes: a first substrate having a plurality of first photoelectric conversion units; a second substrate having a plurality of second photoelectric conversion units; a microlens that forms an image of light; a selector that selects light that has passed through only one of two pupil regions in an exit pupil of an imaging lens in light passed through the microlens and transmitted through the first photoelectric conversion units; a refractor that refracts the light selected by the selector to a side of the second photoelectric conversion units; a first wiring arranged on the first substrate to transmit signals for imaging signals generated by the plurality of first photoelectric conversion units; and a second wiring arranged on the second substrate to transmit signals for focus detection using a phase difference detection method, which are generated by the plurality of second photoelectric conversion units.

### CROSS REFERENCE TO RELATED APPLICATIONS

This application is a continuation application based on a PCT International Application No. PCT/JP2015/053203, filed on Feb. 5, 2015, whose priority is claimed on Japanese Patent Application No. 2014-020479, filed on Feb. 5, 2014. Both of the contents of the PCT International Application and the Japanese Application are incorporated herein by reference.

### BACKGROUND OF THE INVENTION

1. Field of the Invention

The present invention relates to a solid-state imaging device and an imaging apparatus that have a structure in which a plurality of substrates overlap each other.

2. Description of Related Art

In recent years, as in an imaging apparatus described in Japanese Unexamined Patent Application, First Publication No. 2009-204964, an imaging apparatus in which a pixel for imaging that forms a subject image, and a pixel for phase difference detection that receives light that has passed through different pupil regions in an exit pupil of an imaging lens are arranged in the same imaging surface is known. This imaging apparatus performs focal point control on the basis of the phase difference of the subject image that is calculated from signals detected by pixels for phase difference detection.

In the following, the imaging apparatus described in Japanese Unexamined Patent Application, First Publication No. 2009-204964 will be described in detail. In this imaging apparatus, a plurality of AF regions were phase difference detection is possible exist in the vicinity of the center of the imaging surface. FIG. 12 illustrates an array of pixels for imaging and pixels for phase difference detection in AF regions Ef.

In each AF region Ef, a plurality of pixel pairs 1f for phase difference detection are provided together with a plurality of pixels for imaging consisting of a B pixel where a blue color filter is arranged, a G pixel where a green color filter is arranged, and an R pixel where a red color filter is arranged. The pixel pairs 1f for phase difference detection are pairs of pixels 1a and 1b for phase difference detection that select light that has passed through an arbitrary pupil region in the exit pupil of the imaging lens by the light-shielding parts 2a and 2b to be described below.

In the AF region Ef, a Gb line L1 and a Gr line L2 are formed as horizontal lines where a plurality of pixels for imaging are arranged in a horizontal direction. In the Gb line L1, G pixels and B pixels are alternately arranged in the horizontal direction. In the Gr line L2, G pixels and R pixels are alternately arranged in the horizontal direction. A Bayer array is configured by alternately arranging the Gb lines L1 and the Gr lines L2 in a vertical direction.

Additionally, Af lines Lf where the pixel pairs 1f for phase difference detection are alternately arrayed in the horizontal direction are periodically provided in the vertical direction in the AF regions Ef.

FIG. 13 illustrates the configuration of a pixel pair 1f for phase difference detection. A cross section of the pixel pair 1f for phase difference detection is illustrated in FIG. 13. The pixel pair 1f for phase difference detection has a pair of pixels 1a and 1b for phase difference detection. The pixels 1a and 1b for phase difference detection have microlenses ML, color filters CF, light-shielding parts 2a and 2b, and photoelectric conversion units PD. An exit pupil EP of the imaging lens is arranged optically in front (upper side of FIG. 13) of the pixel pair 1f for phase difference detection.

The light-shielding parts 2a and 2b separate light Ta that has passed through a left pupil region Qa of the exit pupil EP of the imaging lens, and light Tb that has passed through a right pupil region Qb of the exit pupil EP of the imaging lens from each other. The pixel 1a for phase difference detection is provided with an oblong (slit-shaped) light-shielding part 2a that is arranged so as to be biased to the left side with respect to a photoelectric conversion unit PD. For this reason, the light Ta that has passed through the left pupil region Qa attic exit pupil EP is radiated to the pixel 1a for phase difference detection via a microlens ML and a color filter CF.

The pixel 1b for phase difference detection is provided with an oblong (slit-shaped) light-shielding part 2b that is arranged so as to be biased to the right side with respect to a photoelectric conversion unit PD. For this reason, the light Tb that has passed through the right pupil region Qb of the exit pupil EP is radiated to the pixel 1b for phase difference detection via a microlens ML and a color filter CF. That is, the light that has passed through the left pupil region Qa and the right pupil region Qb that are biased in leftward and rightward directions that are directions opposite to each other in the exit pupil EP of the imaging lens is received in the pixel pair 1f for phase difference detection.

A signal group detected by a plurality of pixels 1a for phase difference detection and a signal group detected by a plurality of pixels 1b for phase difference detection, which are arranged on one certain AF line L1, are acquired. A focal point is calculated by detecting the phase difference of the light, which has passed through the left pupil region Qa and the right pupil region Qb, which are biased in leftward and rightward directions that are directions opposite to each other in the exit pupil EP of the imaging lens, respectively, using the acquired signal groups.

However, in the imaging apparatus described in Japanese Unexamined Patent Application, First Publication No. 2009-204964, the pixels for phase difference detection are arranged instead of some pixels fir imaging. Therefore, there is a problem that the resolution of imaging signals decreases.

In order to solve this problem, Japanese Unexamined Patent Application, First Publication No. 2013-187475 discloses a solid-state imaging device in which a first substrate having pixels for imaging that generate signals for imaging a subject image, and a second substrate having pixels for phase difference detection that generate signals for detecting the phase difference of a subject image and calculating a focal point are stacked on each other. In the solid-state imaging device described in Japanese Unexamined Patent Application, First Publication No. 2013-187475, the pixels for imaging and the pixels for phase difference detection are respectively divided and arranged on the first substrate and the second substrate. For this reason, signals used for focus detection using a phase difference detection method can be generated while reducing a reduction in the resolution of imaging signals.

In the following, a solid-state imaging device described in Japanese Unexamined Patent Application, First Publication No. 2013-187475 will be described. FIG. 14 illustrates the configuration of the solid-state imaging device described in Japanese Unexamined Patent Application, First Publication No. 2013-187475. A section of the solid-state imaging device is illustrated in FIG. 14. The solid-state imaging device illustrated in FIG. 14 has a first substrate 80, a second substrate 90 stacked on the first substrate 80, microlenses ML formed on the principal surface (a widest surface among a plurality of surfaces that constitute the surface of the substrate) of the first substrate 80, and color filters CF.

The color filters CF are formed on the principal surface of the first substrate 80, and the microlenses ML are respectively formed on the color filters CF. Although a plurality of microlenses ML exist in FIG. 14, a reference sign corresponding to one microlens ML is illustrated as their representative. Additionally, although a plurality of color filters CF exist in FIG. 14, a reference sign corresponding to one color filter CF is illustrated as their representative.

The microlenses ML form an image of light from a subject that has passed through an imaging lens arranged optically in front of the solid-state imaging device. The color filters CF transmit light components of wavelengths corresponding to predetermined colors. For example, red, green, and blue color filters CF are arranged so as to constitute a two-dimensional Bayer array.

The first substrate 80 has a first semiconductor layer 800 and a first wiring layer 810. The first semiconductor layer 800 has first photoelectric conversion units 801a and 801b that convert light that has entered into signals.

The first wiring layer 810 has first wirings 811, first vias 812, and a first interlayer insulator 813. Although a plurality of first wirings 811 exist in FIG. 14, a reference sign corresponding to one first wiring 811 is illustrated as their representative. Additionally, although a plurality of first vias 812 exist in FIG. 14, a reference sign corresponding to one first via 812 is illustrated as their representative.

The first wirings 811 are thin films on which wiring patterns are formed. The first wirings 811 transmit signals, which are generated by the first photoelectric conversion units 801a and 801b, and other signals (power source voltages, ground voltages, and the like). In the example illustrated in FIG. 14, four layers of first wirings 811 are formed. The first wiring 811 formed in a fourth layer nearest to the second substrate 90 among the four layers is formed as a light-shielding part 811a.

The light-shielding part 811a has openings 8110a and 8110b through which only a portion of light that has entered the first substrate 80 passes. Inner walls of the openings 8110a and 8110b consist of side walls of the light-shielding part 811a.

Each first via 812 connects different layers of first wirings 811. In the first wiring layer 810, portions other than the first wirings 811 and the first vias 812 are constituted of the first interlayer insulator 813.

The second substrate 90 has a second semiconductor layer 900 and a second wiring layer 910. The second semiconductor layer 900 has second photoelectric conversion units 901a and 901b that convert light that has entered into signals.

The second wiring layer 910 has second wirings 911, second vias 912, a second interlayer insulator 913, and MOS transistors 920. Although a plurality of second wirings 911 exist in FIG. 14, a reference sign corresponding to one second wiring 911 is illustrated as their representative. Additionally, although a plurality of second vias 912 exist in FIG. 14, a reference sign corresponding to one second via 912 is illustrated as their representative. Additionally, although a plurality of MOS transistors 920 exist in FIG. 14, a reference sign corresponding to one MOS transistor 920 is illustrated as their representative.

The second wirings 911 are thin films on which wiring patterns are formed. The second wirings 911 transmit signals, which are generated by the first photoelectric conversion units 801a and 801b, signals, which are generated by the second photoelectric conversion units 901a and 901b, and other signals (power source voltages, ground voltages, and the like). In the example illustrated in FIG. 14, two layers of second wirings 911 are formed.

Each second via 912 connects different layers of second wirings 911. In the second wiring layer 910, portions other than the second wirings 911 and the second vias 912 are constituted of the second interlayer insulator 913.

Each MOS transistor 920 has a source region and a drain region that are diffusion regions formed in the second semiconductor layer 900, and a gate electrode formed in the second wiring layer 910. The source region and the drain region are connected to each second via 912. The gate electrode is arranged between the source region and the drain region. The MOS transistors 920 process signals transmitted by the second wirings 911 and the second vias 912.

The first substrate 80 and the second substrate 90 are electrically connected together in an interface between the first substrate 80 and the second substrate 90 via the first vias 812 and the second vias 912.

In the solid-state imaging device illustrated in FIG. 14, imaging signals can be generated from signals generated by the first photoelectric conversion units 801a and 801b, and signals (signals for phase difference calculation) used for focus detection using a phase difference detection method can be generated from signals generated by the second photoelectric conversion units 901a and 901b.

### SUMMARY OF THE INVENTION

A solid-state imaging device related to a first aspect of the invention is a solid-state imaging device including a first substrate having a plurality of first photoelectric conversion units arranged in two dimensions; a second substrate having a plurality of second photoelectric conversion units arranged in two dimensions and being stacked on the first substrate; a microlens arranged oil the surface of the first substrate to form an image alight that has passed through an imaging lens; a selector arranged between the first photoelectric conversion units and the second photoelectric conversion units to select light that has passed through only one of two pupil regions in an exit pupil of the imaging lens in light passed through the microlens and transmitted through the first photoelectric conversion units; a refractor arranged between the selector and the second photoelectric conversion units to refract the light selected by the selector to a side of the second photoelectric conversion units; a first wiring arranged on the first substrate to transmit signals for imaging signals generated by the plurality of first photoelectric conversion units; and a second wiring arranged on the second substrate to transmit signals for focus detection using a phase difference detection method, which are generated by the plurality of second photoelectric conversion units.

Additionally, according to the solid-state imaging device related to a second aspect of the invention based on the first aspect, an interlayer insulator arranged between the first photoelectric conversion units and the second photoelectric conversion units may be further included, and the refractor may be embedded in the interlayer insulator, and may be formed of a material having a higher refractive index than that of the interlayer insulator.

Additionally, according to the solid-state imaging device related to a third aspect of the invention based on the second aspect, the refractor may be a light pipe that totally reflects the light refracted to the side of the second photoelectric conversion units and guides the light to the second photoelectric conversion units.

Additionally, according to the solid-state imaging device related to a fourth aspect of the invention based on the first aspect, the selector may include a light-shielding part having openings formed at positions through Which the light that has passed through only one of the two pupil regions of the imaging lens passes.

Additionally, according to the solid-state imaging device related to a fifth aspect of the invention based on the fourth aspect, a surface of the refractor that faces the first photoelectric conversion units may be arranged in vicinity of the openings.

Additionally, according to the solid-state imaging device related to a sixth aspect of the invention based on the fourth aspect, the openings may be arranged inside an outline of the refractor when viewed from a direction perpendicular to a principal surface of the first substrate or the second substrate.

Additionally, according to the solid-state imaging device related to a seventh aspect of the invention based on the fourth aspect, an optical absorber, which absorbs light other than the light that has passed through only one of the two pupil regions in the exit pupil of the imaging lens in the light transmitted through the first photoelectric conversion units, may be arranged in regions other than regions where the openings are formed, in a surface of the selector that faces the first photoelectric conversion units.

Additionally, according to the solid-state imaging device related to an eighth aspect of the invention based on the first aspect, a surface of the refractor that faces the first photoelectric conversion units may have a curvature such that the light selected by the selector is condensed.

Additionally, according to the solid-state imaging device related to a ninth aspect of the invention based on the first aspect, a plurality of units among the plurality of first photoelectric conversion units may overlap each of the plurality of second photoelectric conversion units when viewed from a direction perpendicular to a principal surface of the first substrate or the second substrate.

Additionally, an imaging apparatus related to a tenth aspect of the invention may include the solid-state imaging device of each of the above aspects.

### BRIEF DESCRIPTION OF THE DRAWINGS

FIG. 1 is a sectional view illustrating a configuration example of a solid-state imaging device according to a first embodiment of the invention.

FIG. 2 is a plan view of the solid-state imaging device according to the first embodiment of the invention.

FIG. 3 is a sectional view illustrating a configuration example of a solid-state imaging device according to a modification example of the first embodiment of the invention.

FIG. 4 is a sectional view illustrating a configuration example of a solid-state imaging device according to a modification example of the first embodiment of the invention.

FIG. 5 is a sectional view illustrating a configuration example of a solid-state imaging device according to a modification example of the first embodiment of the invention.

FIG. 6 is a sectional view illustrating a configuration example of a solid-state imaging device according to a modification example of the first embodiment of the invention.

FIG. 7 is a sectional view illustrating a configuration example of a solid-state imaging device according to a modification example of the first embodiment of the invention.

FIG. 8 is a sectional view illustrating a configuration example of a solid-state imaging device according to a second embodiment of the invention.

FIG. 9 is a plan view of the solid-state imaging device according to the second embodiment of the invention.

FIG. 10 is a sectional view illustrating a configuration example of a solid-state imaging device according to a third embodiment of the invention.

FIG. 11 is a block diagram showing the configuration example of an imaging apparatus according to a fourth embodiment of the invention.

FIG. 12 is a reference view illustrating the array of pixels for imaging and pixels for phase difference detection in AF regions of a related-art solid-state imaging device.

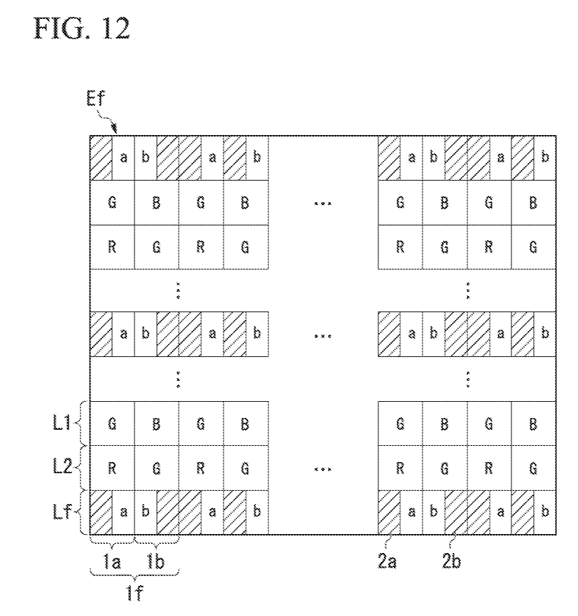

FIG. 13 is a sectional view illustrating the configuration of a pixel pair for phase difference detection of the related-art solid-state imaging device.

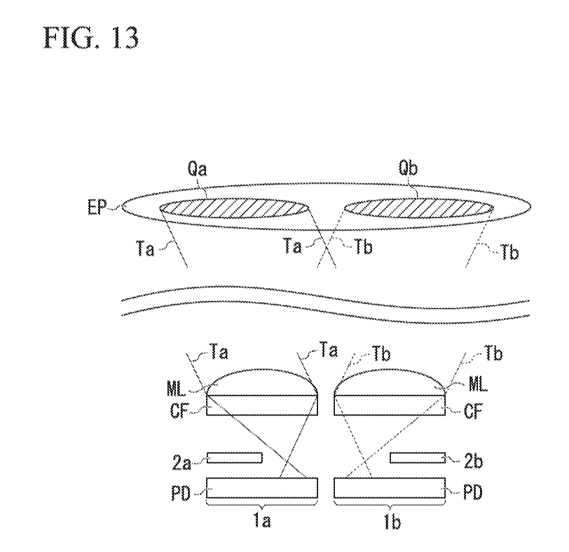

FIG. 14 is a sectional view illustrating the configuration of the related-art solid-state imaging device.

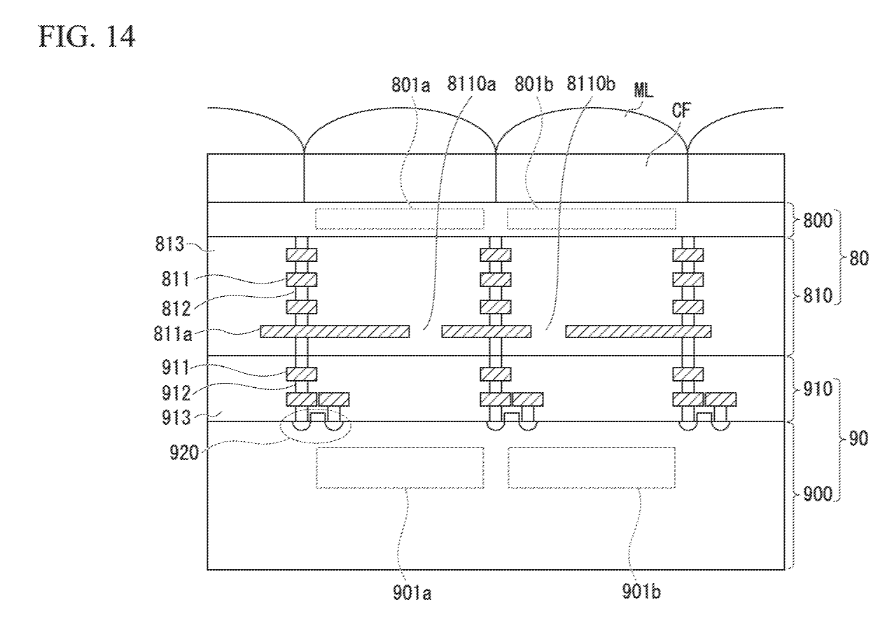

FIG. 15 is a sectional view for describing the problems of the related-art solid-state imaging device.

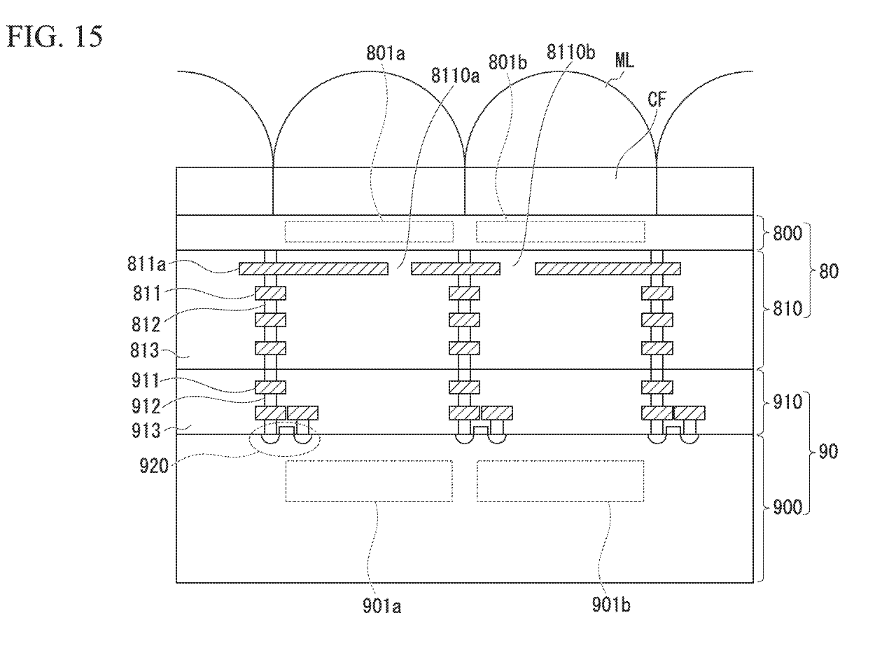

FIG. 16 is a sectional view for describing the problems of the related-art solid-state imaging device.

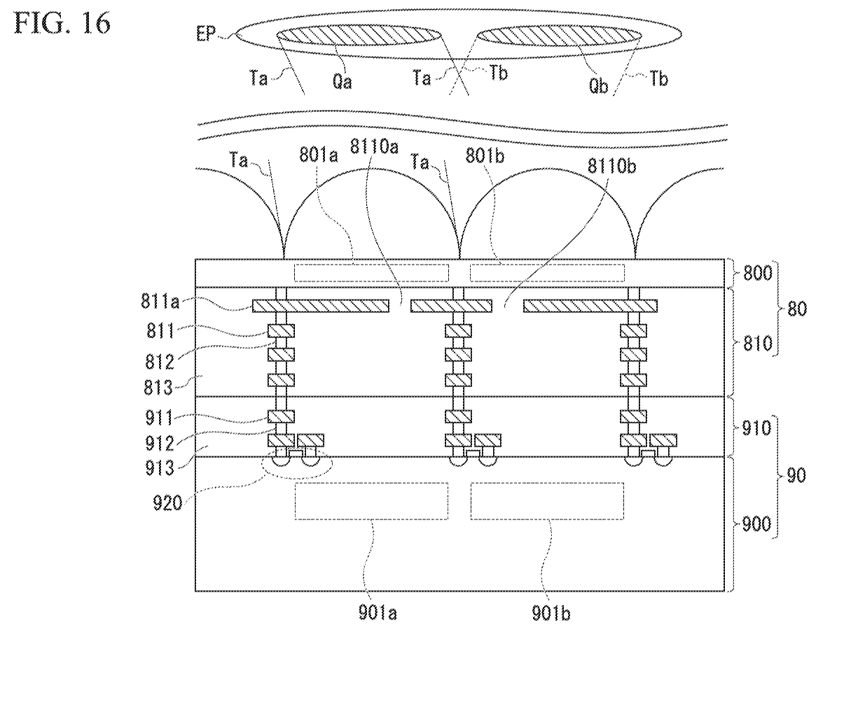

FIG. 17 is a sectional view for describing the problems of the related-art solid-state imaging device.

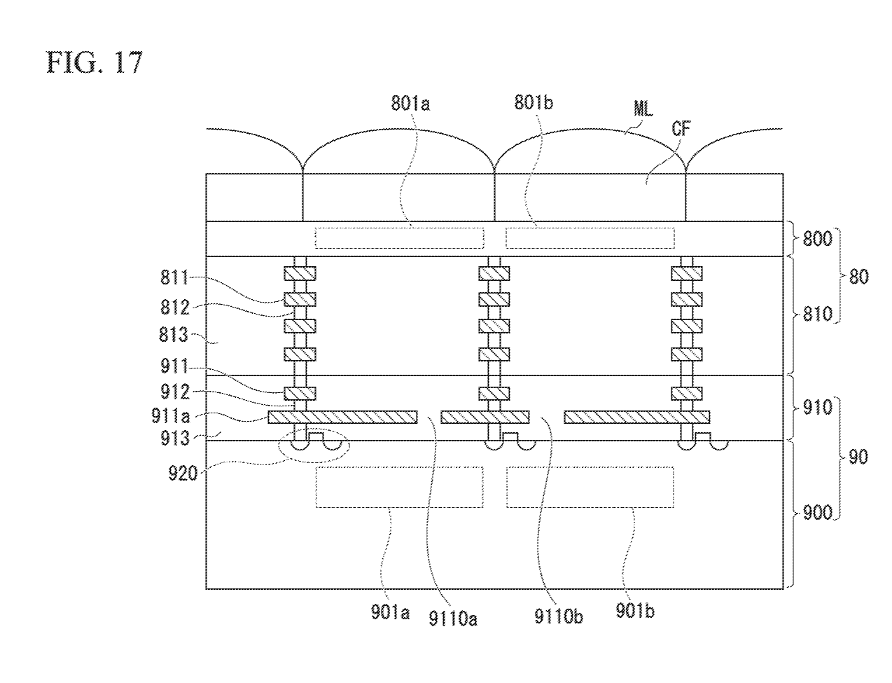

### DETAILED DESCRIPTION OF THE INVENTION

Embodiments of the invention will be described below referring to the drawings.

### First Embodiment

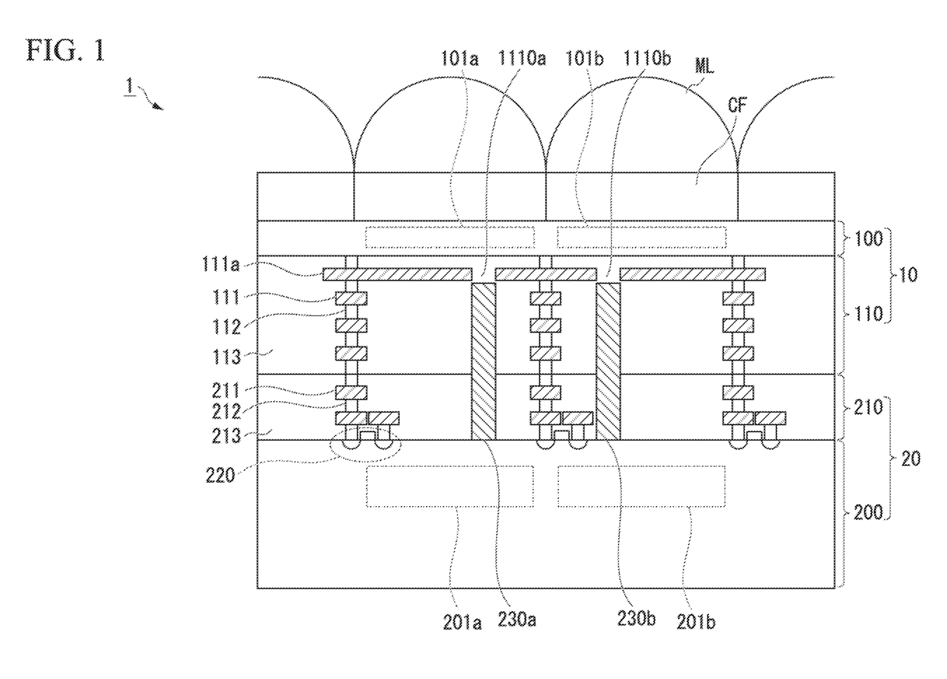

First, a first embodiment of the invention will be described. FIG. 1 illustrates a configuration example of a solid-state imaging device according to the present embodiment. A section of the solid-state imaging device is illustrated in FIG. 1. The solid-state imaging device 1 illustrated in FIG. 1 has a first substrate 10, a second substrate 20 stacked on the first substrate 10, microlenses ML formed on the surface of the first substrate 10 and color filters CF.

The dimensions of portions that constitute the solid-state imaging device illustrated in FIG. 1 do not necessarily follow the dimensions illustrated in FIG. 1. The dimensions of the portions that constitute the solid-state imaging device illustrated in FIG. 1 may be any arbitrary value.

The color filters CF are formed on a principal surface (a widest surface among a plurality of surfaces that constitute the surface of a substrate) of the first substrate 10, and the microlenses ML are respectively formed on the color filters CF.

Although a plurality of microlenses ML exist in FIG. 1, a reference sign corresponding to one microlens ML is illustrated as their representative. Additionally, although a plurality of color filters CF exist in FIG. 1, a reference sign corresponding to one color filter CF is illustrated as their representative.

The microlenses ML form an image of light from a subject, which has passed through an imaging lens arranged optically in front of the solid-state imaging device. The color filters CF transmit light components of wavelengths corresponding to predetermined colors. For example, red, green, and blue color filters CF are arranged so as to constitute a two-dimensional Bayer array.

The first substrate 10 has a first semiconductor layer 100 and a first wiring layer 110. The first semiconductor layer 100 and the first wiring layer 110 overlap each other in a direction (for example, a direction substantially perpendicular to the principal surface of the first substrate 10) crossing the principal surface of the first substrate 10. Additionally, the first semiconductor layer 100 and the first wiring layer 110 are in contact with each other.

The first semiconductor layer 100 has first photoelectric conversion units 101a and 101b. The first semiconductor layer 100 is made of materials including semiconductors, such as silicon (Si). The first semiconductor layer 100 has a first surface that is in contact with the first wiring layer 110, and a second surface that is in contact with the color filters CF and is opposite to the first surface. The second surface of the first semiconductor layer 100 constitutes one of principal surfaces of the first substrate 10. Light, which has entered the second surface of the first semiconductor layer 100, proceeds into the first semiconductor layer 100 and enters the first photoelectric conversion units 101a and 101b. The first photoelectric conversion units 101a and 101b are made of for example, semiconductor materials having an impurity concentration that is different from that of semiconductor materials that constitute the first semiconductor layer 100. The first photoelectric conversion units 101a and 101b convert the light that has entered into signals.

The solid-state imaging device has a plurality of the first photoelectric conversion units 101a and 101b. When viewed from the direction perpendicular to the principal surface of the first substrate 10 or the second substrate 20, that is, when the first substrate 10 or the second substrate 20 is planarly viewed, the plurality of first photoelectric conversion units 101a and 101b are arranged in a matrix.

The first wiring layer 110 has first wirings 111, first vias 112, and a first interlayer insulator 113. Although a plurality of first wirings 111 exist in FIG. 1, a reference sign corresponding to one first wiring 111 is illustrated as their representative. Additionally, although a plurality of first vias 112 exist in FIG. 1, a reference sign corresponding to one first via 112 is illustrated as their representative.

The first wirings 111 are made of materials (for example, metal, such as aluminum (Al) or copper (Cu)) having conductivity. The first wiring layer 110 has a first surface that is in contact with the second substrate 20, and a second surface that is in contact with the first semiconductor layer 100 and is opposite to the first surface. The first surface of the first wiring layer 110 constitutes one of the principal surfaces of the first substrate 10.

The first wirings 111 are thin films on which wiring patterns are formed. The first wirings 111 transmit signals for imaging signals, which are generated by the first photoelectric conversion units 101a and 101b, and other signals (power source voltages, ground voltages, and the like). As the first wirings 111 only one layer of a first wiring 111 may be formed, or a plurality of layers of first wirings 111 may be formed. In the example illustrated in FIG. 1, four layers of first wirings 111 are formed. The first wiring 111 formed in a first layer nearest to the first semiconductor layer 100 among the four layers is formed as a light-shielding part 111a. The light-shielding part 111a will be described below.

The first vias 112 are made of materials having conductivity. Each first via 112 connects different layers of first wirings 111. In the first Firing layer 110, portions other than the first wirings 111 and the first vias 112 are constituted of the first interlayer insulator 113 formed of, for example, silicon dioxide (SiO2) or the like.

The second substrate 20 has a second semiconductor layer 200 and a second wiring layer 210. The second semiconductor layer 200 and the second wiring layer 210 overlap each other in a direction (for example, a direction substantially perpendicular to a principal surface of the second substrate 20) crossing the principal surface of the second substrate 20. Additionally, the second semiconductor layer 200 and the second wiring layer 210 are in contact with each other.

The second semiconductor layer 200 has second photoelectric conversion units 201a and 201b. The second semiconductor layer 200 is made of materials including semiconductors such as silicon (Si). The second photoelectric conversion units 201a and 201b are made of, for example, semiconductor materials having an impurity concentration that is different from that of semiconductor materials that constitute the second semiconductor layer 200. The second photoelectric conversion unit 201a is formed in a region corresponding to the first photoelectric conversion unit 101a, and the second photoelectric conversion unit 201b is formed in a region corresponding to the first photoelectric conversion unit 101b. The second wiring layer 210 has a first surface that is in contact with the second semiconductor layer 200, and a second surface that is opposite to the first surface. The second surface of the second semiconductor layer 200 constitutes one of the principal surfaces of the second substrate 20. Light, which has entered the first surface of the second semiconductor layer 200, proceeds into the second semiconductor layer 200 and enters the second photoelectric conversion units 201a and 201b. The second photoelectric conversion units 201a and 201b convert the light that has entered into signals.

The solid-state imaging device has a plurality of the second photoelectric conversion units 201a and 201b. When viewed from the direction perpendicular to the principal surface of the first substrate 10 or the second substrate 20, that is, when the first substrate 10 or the second substrate 20 is planarly viewed, the plurality of second photoelectric conversion units 201a and 201b are arranged in a matrix.

The second wiring layer 210 has second wirings 211, second vias 212, a second interlayer insulator 213, and MOS transistors 220. Although a plurality of second wirings 211 exist in FIG. 1, a reference sign corresponding to one second wiring 211 is illustrated as their representative. Additionally, although a plurality of second vias 212 exist in FIG. 1, a reference sign corresponding to one second via 212 is illustrated as their representative. Additionally, although a plurality of MOS transistors 220 exist in FIG. 1, a reference sign corresponding to one MOS transistor 220 is illustrated as their representative.

The second wirings 211 are made of materials (for example, metal, such as aluminum (Al) or copper (Cu)) having conductivity. The second wiring layer 210 has a first surface that is in contact with the first wiring layer 110, and a second surface that is in contact with the second semiconductor layer 200 and is opposite to the first surface. The first surface of the second wiring layer 210 constitutes one of the principal surfaces of the second substrate 20.

The second wirings 211 are thin films can which wiring patterns are formed. The second wirings 211 transmit signals for imaging signals, which are generated by the first photoelectric conversion units 101a and 101b, signals for focus detection using a phase difference detection method, which are generated by the second photoelectric conversion units 201a and 201b, and other signals (power source voltages, ground voltages, and the like). As the second wirings 211, only one layer of a second wiring 211 may be formed, or a plurality of layers of second wirings 211 may be formed. In the example illustrated in FIG. 1, two layers of s and wirings 211 are formed.

The second vias 212 are made of materials having conductivity. Each second via 212 connects different layers of second wirings 211. In the second wiring layer 210, portions other than the second wirings 211 and the second vias 212 are constituted of the second interlayer insulator 213 formed of, for example silicon dioxide (SiO2) or the like.

Each MOS transistor 220 has a source region and a drain region that are diffusion regions formed in the second semiconductor layer 200, and a gate electrode formed in the second wiring layer 210.

The source region and the drain region are connected to each second via 212. The gate electrode is arranged between the source region and the drain region. The MOS transistors 220 process signals transmitted by the second wirings 211 and the second via 212.

The first substrate 10 and the second substrate 20 are connected together in a state in which the first wiring layer 110 of the first substrate 10 and the second wiring layer 210 of the second substrate 20 face each other. A first via 112 of the first wiring layer 110 and a second via 212 of the second wiring layer 210 are electrically connected together in an interface between the first substrate 10 and the second substrate 20.

The light-shielding part 111a is arranged at positions (image forming points) where an image of light is formed by the microlens ML in the direction perpendicular to the principal surface of the first substrate 10 or the second substrate 20. Additionally, the light-shielding part 111a has openings 1110a and 1110b formed at positions where an image of light that has passed through only one of two pupil regions in an exit pupil of the imaging lens is formed. Inner walls of the openings 1110a and 1110b consist of side walls of the light-shielding part 111a.

The opening 1110a is arranged to correspond to the first photoelectric conversion unit 101a. The opening 1110a is turned at a position through which light, which has passed through only one of the two pupil regions in the exit pupil of the imaging lens in light passed through a microlens ML and transmitted through the first photoelectric conversion unit 101a passes. The opening 1110a is formed at a position biased to the right of the center of the microlens ML.

The opening 1110b is arranged to correspond to the first photoelectric conversion unit 101b. The opening 1110b is formed at a position through which light, which has passed through only one (a pupil region different from the pupil region through which the light passing through the opening 1110a has passed) of the two pupil regions in the exit pupil of the imaging lens in the light passed through microlens ML and transmitted through the first photoelectric conversion unit 101b, passes. The opening 1110b is formed at a position biased to the left of the center of the microlens ML.

The light-shielding part 111a is arranged between the first photoelectric conversion units 101a and 101b and the second photoelectric conversion units 201a and 201b, and functions as a selector that selects the light that has passed through only one of the two pupil regions in the exit pupil of the imaging lens in the light passed through the microlenses ML and transmitted through the first photoelectric conversion units 101a and 101b.

In a plane parallel to the principal surface of the first substrate 10, a position where a microlens ML forms an image of light is a position according to a pupil region through which the light has passed. The opening 1110a is formed at a position where an image of light, which has passed through a left pupil region out of left and right pupil regions of the imaging lens, is formed. Therefore, the light-shielding part 111a selectively passes the light, which has passed through the left pupil region, through the opening 1110a. Additionally, the opening 1110b is formed at a position where an image of light which has passed through a right pupil region out of the left and right pupil regions of the imaging lens, is formed. Therefore, the light-shielding part 111a selectively passes the light, which has passed through the right pupil region, through the opening 1110b. In the present embodiment, one layer of the first wiring 111 constitutes the light-shielding part 111a. However, the light-shielding part may be realized by a separate structure from the first wiring 111.

Light pipes 230a and 230b are formed astride the first wiring layer 110 and the second wiring layer 210. The light pipe 230a is formed between the first photoelectric conversion unit 101a and the second photoelectric conversion unit 201a and between the light-shielding part 111a and the second photoelectric conversion unit 201a. The light pipe 230b is formed between the first photoelectric conversion unit 101b and the second photoelectric conversion unit 201b and between the light-shielding part 111a and the second photoelectric conversion unit 201b.

The light pipes 230a and 230b are pillar-shaped structures that are elongated in the direction (for example, the direction substantially perpendicular to the principal surface) crossing the principal sort of the first substrate 10, and have first surfaces that face the first photoelectric conversion units 101a and 101b, second surfaces that face the second photoelectric conversion units 201a and 201b, and third surfaces (side surfaces) connected to the first surfaces and the second surfaces. The light pipe 230a is arranged at a position corresponding to the opening 1110a. The first surfaces of the light pipes 230a and 230b, as illustrated in FIG. 1, are located on the surface of the light-shielding part 111a closer to the side of the second semiconductor layer 200 than the side of the first wiring 111. Accordingly, the light, which has been transmitted through the first photoelectric conversion unit 101a, selected by the light-shielding part 111a, and passed through the opening 1110a, enters the first surface of the light pipe 230a. Additionally, the light pipe 230b is arranged at a position corresponding to the opening 1110b. The light, which is transmitted through the first photoelectric conversion unit 101b, selected by the light-shielding part 111a, and passed through the opening 1110b, enters the first surface of the light pipe 230b. The second surfaces of the light pipes 230a and 230b are in contact with the second semiconductor layer 200.

The light pipes 230a and 230b are embedded in the first interlayer insulator 113 and the second interlayer insulator 213 arranged between the first photoelectric conversion units 101a and 101b and the second photoelectric conversion units 201a and 201b, and are formed of materials having a higher refractive index than that of the first interlayer insulator 113 and the second interlayer insulator 213. For example, the light pipes 230a and 230b are formed of dielectrics (insulators) having a higher refractive index than that of the first interlayer insulator 113 and the second interlayer insulator 213.

The light pipes 230a and 230b function as refractors that refract light, which has entered the first surfaces of the light pipes 230a and 230b, to the side of the second photoelectric conversion units 201a and 201b. Accordingly, the light pipes 230a and 230b brine the direction of the light, which has entered the first surfaces of the light pipes 230a and 230b, closer to the direction (the direction perpendicular to the principal surface of the first substrate 10 or the second substrate 20) perpendicular to the second photoelectric conversion units 201a and 201b.

The light pipes 230a and 230b guide the light refracted to the side surfaces of the light pipes 230a and 230b to the second photoelectric conversion units 201a and 201b side while totally reflecting the light with the side surfaces of the second photoelectric conversion units 201a and 201b. Accordingly, the light pipes 230a and 230b cause larger amounts of light than that in a case where the light pipes 230a and 230b are not provided to enter in the second photoelectric conversion units 201a and 201b. The light pipes 230a and 230b function as optical waveguides that guide the light, which has entered the first surfaces of the light pipes 230a and 230b, to the second photoelectric conversion units 201a and 201b.

In order to cause the larger amounts of the light, which has passed through the openings 1110a and 1110b, to enter the light pipes 230a and 230b, the first surfaces of the light pipes 230a and 230b may be arranged in the vicinity of the openings 1110a and 1110b. Additionally, when viewed from the direction perpendicular to the principal surface of the first substrate 10 or the second substrate 20, that is, when the first substrate 10 or the second substrate 20 is planarly viewed, portions of the light pipes 230a and 230b may overlap the openings 1110a and 1110b.

Although a configuration in which all the light, which has entered the first surfaces of the tight pipes 230a and 230b, is confined inside the light pipes 230a and 230b by total reflection and are guided to the second photoelectric conversion units 201a and 201b may be adopted, portion of the light, which has entered the first surfaces of the light pipes 230a and 230b, may pass through the side surfaces of the light pipes 230a and 230b and enter the first interlayer insulator 113. Even in such a case, by refracting the light to the side of the second photoelectric conversion units 201a and 201b on the first surfaces of the light pipes 230a and 230b and advancing the light inside the light pipes 210a and 230b, the possibility that the light may reach the second photoelectric conversion units 201a and 201b without the light being blocked by the first wirings 111 and the second wirings 211 becomes high.

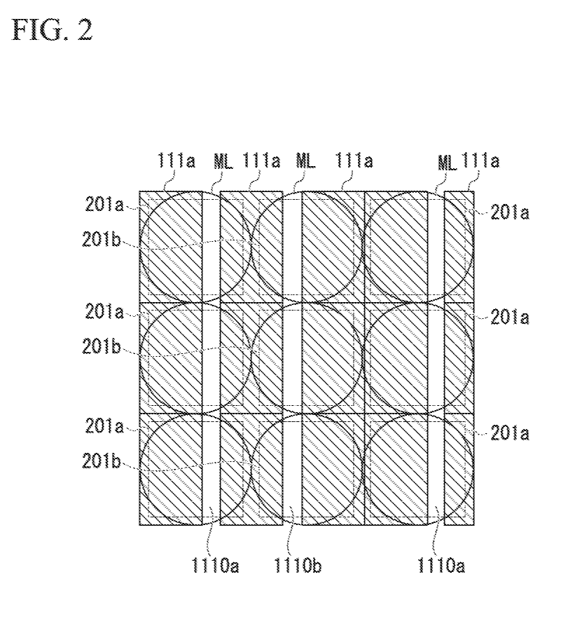

FIG. 2 illustrates a state in which the solid-state imaging device 1 illustrated in FIG. 1 is planarly viewed. A state in which the solid-state imaging device 1 is viewed from the principal surface side of the second substrate 20 connected to the first substrate 10 is illustrated in FIG. 2.

The second photoelectric conversion units 201a and 101b are arranged in a two-dimensional matrix. One microlens ML is arranged to correspond to one second photoelectric conversion unit 201a or 201b. Although the first photoelectric conversion units 101a and 101b are omitted in FIG. 2, the first photoelectric conversion units 101a and 101b are arranged at positions that overlap the second photoelectric conversion units 201a and 201b in FIG. 2.

An oblong opening 1110a arranged so as to be biased to the right side with respect to the second photoelectric conversion unit 201a is formed at a position that overlaps the second photoelectric conversion unit 201a. An oblong opening 1110b biased to the left side with respect to the second photoelectric conversion unit 201b is formed at a position that overlaps the second photoelectric conversion unit 201b.

The opening 1110a and the opening 1110b are arranged so that the planar positions thereof within the respective pixels become bilaterally symmetrical. Therefore, the light, which has passed through the left and right pupil regions, which are biased in leftward and rightward directions that are directions opposite to each other in the exit pupil of the imaging lens, respectively, is received in the second photoelectric conversion unit 201a and the second photoelectric conversion unit 201b. A plurality of pixels that are arranged at positions where the openings represented by the opening 1110a and the opening 1110b are bilaterally symmetrical or vertically symmetrical and become pairs are arranged in two dimensions within an imaging surface of the solid-state imaging device 1.

In FIG. 2, the light pipes 230a and 230b are omitted. The shapes of the first surfaces and the second surfaces of the light pipes 230a and 230b are, for example, polygons such as quadrangles or hexagons, or circles. The utilization efficiency of the light that enters the first surfaces of the light pipes 230a and 230b and is guided to the second photoelectric conversion units 201a and 201b can be made the highest by forming the shape of the first surfaces and the second surfaces of the light pipes 230a and 230b into a circle.

The light, which has entered the solid-state imaging device 1, passes through the microlenses ML and the color filters Cf, and enters the first photoelectric conversion units 101a and 101b. The light, which has entered the first photoelectric conversion units 101a and 101b, is converted into first signals according to the quantity of the light that has entered the first photoelectric conversion units 101a and 101b by the first photoelectric conversion units 101a and 101b. The first signals generated by the first photoelectric conversion units 101a and 101b are transmitted to the second substrate 20 via the first wirings 111 and the first via 112 in the first wiring layer 110. The first signals transmitted to the second substrate 20 are transmitted via the second wirings 211 and the second via 212 in the second wiring layer 210, and are processed by the MOS transistor 220 or the like. Finally, the first signals processed by the MOS transistor 220 or the like are output from the solid-state imaging device 1 as imaging signals.

Additionally, the light, which has passed through the left and right pupil regions of the imaging lens in the light transmitted through the first photoelectric conversion units 101a and 101b, passes through the openings 1110a and 1110b. The light, which has passed through the openings 1110a and 1110b, passes through the first surfaces of the light pipes 230a and 230b, and enters the light pipes 230a and 230b. When passing through the first surfaces of the light pipes 230a and 230b, the light is refracted to the side of the second photoelectric conversion units 201a and 201b.

A major portion of the light, which has entered the light pipes 230a and 230b, advances inside the light pipes 230a and 230b while being totally reflected by the side surfaces of the light pipes 230a and 230b. Moreover, the light, which has advanced inside the light pipes 230a and 230b, passes through the second surfaces of the light pipes 230a and 230b, and enters the second semiconductor layer 200. The light, which has entered the second semiconductor layer 200, advances inside the second semiconductor layer 200, and enters the second photoelectric conversion units 201a and 201b.

The light, which enters the second photoelectric conversion units 201a and 201b via the light pipes 230a and 230b, is the light that has passed through the left and right pupil regions of the imaging lens. This light is converted into second signals according to the quantity of the light that has entered the second photoelectric conversion units 201a and 201b by the second photoelectric conversion units 201a and 201b. The second signals generated by the second photoelectric conversion units 201a and 201b are transmitted via the second wirings 211 and the second via 212 in the second wiring layer 210, and are processed by the MOS transistor 220 or the like. The second signals processed by the MOS transistor 220 or the like become signals for focus detection.

In the following, a focal detecting method in the present embodiment will be described. The second photoelectric conversion unit 201a receives the light that has been passed through the opening 1110a and transmitted through the light pipe 230a. That is, the second photoelectric conversion unit 201a receives the light that has passed through the left pupil region in the exit pupil of the imaging lens. The second photoelectric conversion unit 201b receives the light that has been passed through the opening 1110b and transmitted through the light pipe 230b. That is, the second photoelectric conversion unit 201b receives the light that has passed through the right pupil region in the exit pupil of the imaging lens. Therefore, the light, which has passed through the pupil regions biased in leftward and rightward directions that are directions opposite to each other in the exit pupil of the imaging lens, is received by the second photoelectric conversion unit 201a and the second photoelectric conversion unit 201b.

A signal group of the second photoelectric conversion unit 201a and a signal group of the second photoelectric conversion unit 201b, which are generated on the basis of the light that has passed through the different pupil regions in the exit pupil of the imaging lens, are acquired. A focal point is calculated by detecting the phase difference of the light, which has passed through the left and right pupil regions, which are biased in leftward and rightward directions that are directions opposite to each other in the exit pupil of the imaging lens, respectively, using these signal groups. The calculation of the focal point may be performed within the solid-state imaging device 1, or may be performed outside the solid-state imaging device 1.

The color filters CF, the first vias 112, the first interlayer insulator 113, the second vias 212, the second interlayer insulator 213, and the MOS transistor 220 are not characteristic structures of the solid-state imaging device according to the present embodiment. Additionally, these structures are not indispensable structures in order to obtain the characteristic effects of the solid-state imaging device according to the present embodiment.

According to the present embodiment, the solid-state imaging device 1 is configured to include the first substrate 10 having the plurality of first photoelectric conversion units 101a and 101b arranged in two dimensions; the second substrate 20 having the plurality of second photoelectric conversion units 201a and 201b arranged in two dimensions and being stacked on the first substrate 10; the microlens ML arranged on the surface of the first substrate 10 to form an image of light that has passed through an imaging lens; a selector (light-shielding part 111a) arranged between the first photoelectric conversion units 101a and 101b and the second photoelectric conversion units 201a and 201b to select the light that has passed through only one of the two pupil regions in the exit pupil of the imagine lens in the light passed through the microlenses ML and transmitted through the first photoelectric conversion units 101a and 101b; a refractor (light pipes 230a and 230b) arranged between the selector and the second photoelectric conversion units 201a and 201b to refract the light selected by the selector to the side of the second photoelectric conversion units 201a and 201b; the first wirings 111 arranged on the first substrate 10 to transmit signals for imaging signals generated by the plurality of first photoelectric conversion units 101a and 101b; and the second wirings 211 arranged on the second substrate 20 to transmit signals for focus detection using a phase difference detection method, which are generated by the plurality of second photoelectric conversion units 201a and 201b.

In the present embodiment, the photoelectric conversion units are arranged on both the first substrate 10 and the second substrate 20. Thus, as compared to a case where photoelectric conversion units for generating signals for imaging signals and photoelectric conversion units for generating signals for focus detection are arranged in the same plane, the focus detection using the phase difference detection method can be performed while reducing degradation in the resolution of the imaging signals.

Additionally, since the light-shielding part 111a that functions as the selector, and the light pipes 230a and 230b that function as the refractor are provided, it is possible to bring positions where the microlenses ML form an image of light, closer to the first photoelectric conversion units 101a and 101b, and the light, which has passed through only one of the two pupil regions in the exit pupil of the imaging lens, easily enters the second photoelectric conversion units 201a and 201b. For this reason, a decrease in the quantity of the light that enters the second photoelectric conversion units 201a and 201b that generate signals for focus detection using the phase difference detection method can be suppressed and signals capable of precisely detecting a focal point can be generated, while suppressing degradation in the sensitivity of the first photoelectric conversion units 101a and 101b that generate signals for imaging signals.

### Modification Example

The color filters CF may be filters for colors other than red, green, and blue (for example, filters for complementary colors, such as cyan, yellow, and magenta). Additionally, the array of the color filters CF may be arrays other than the Bayer array.

In the present embodiment, although the light-shielding part 111a is arranged in the first layer of the first wiring layer 110, the light-shielding part 111a may be arranged in a second layer or a third layer of the first wiring layer 110.

Although the solid-state imaging device 1 illustrated in FIG. 1 has the two substrates, the solid-state imaging device may have three or more substrates. Two substrates adjacent to each other among a plurality of substrates of the solid-state imaging device just has to have the same structures as those of the first substrate 10 and the second substrate 20.

In the present embodiment, the light-shielding part 111a is provided as a method of selecting the light that has passed through the pupil regions in the exit pupil of the imaging lens. However, other methods may be provided. In the following, the other methods of selecting the light that has passed through the pupil regions in the exit pupil of the imaging lens will be described.

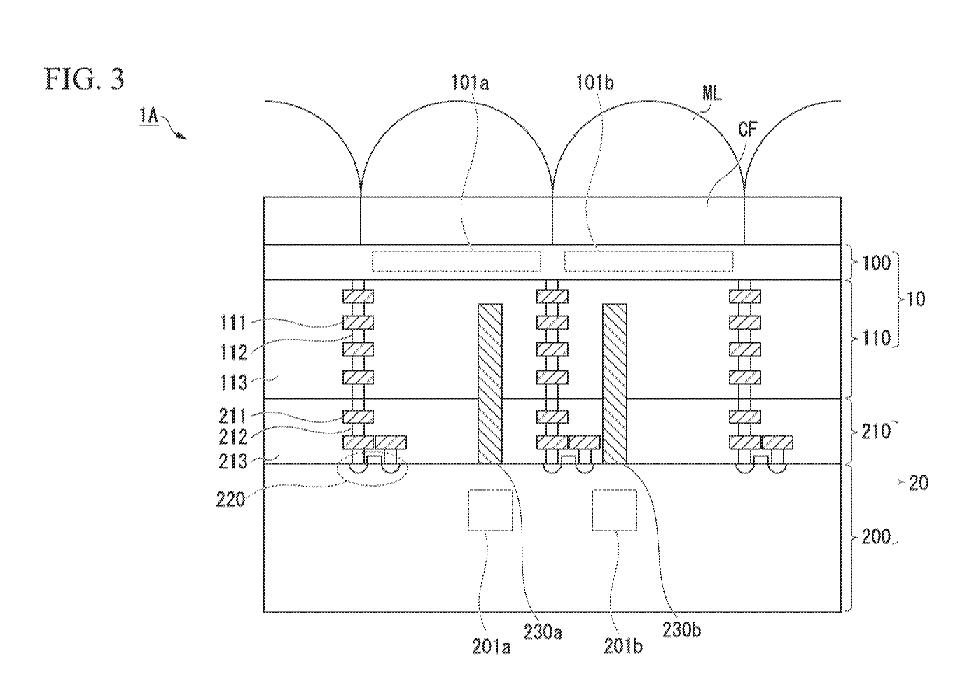

FIG. 3 illustrates a configuration example of a solid-state imaging device 1A according to the present modification example. A section of the solid-state imaging device 1A is illustrated in FIG. 3. The description of the already described portion will be omitted.

The solid-state imaging device 1A illustrated in FIG. 3 is not provided with the light-shielding part 111a. The first surfaces of the surfaces of the light pipes 230a and 230b that face the first photoelectric conversion units 101a and 101b are arranged at positions where the light, which has passed through only one of the two pupil regions in the exit pupil of the imaging lens, enters. That is, the light, which has passed through only one of the two pupil regions in the exit pupil of the imaging lens in the light passed through the imaging lens, enters the first surfaces of the light pipes 230a and 230b. In the solid-state imaging device 1A illustrated in FIG. 3, the first surfaces of the light pipes 230a and 230b function as a selector that selects the light that has passed through only one of the two pupil regions in the exit pupil of the imaging lens in the light passed through the microlenses ML and transmitted through the first photoelectric conversion units 101a and 101b.

A major portion of the light, which has entered the first surfaces of the light pipes 230a and 230b, is guided to the second photoelectric conversion units 202a and 201b by the light pipes 230a and 230b, as mentioned above. Since the solid-state imaging device 1A illustrated in FIG. 3 is not provided with the light-shielding part 111a, the light, which has passed through the other pupil region of the two pupil regions in the exit pupil of the imaging lens, also enters the second semiconductor layer 200. In order to keep this light from entering the second photoelectric conversion units 201a and 201b, the second photoelectric conversion units 201a and 201b are formed in the vicinity of the light pipes 230a and 230b. The width, in the horizontal direction, of the second photoelectric conversion units 201a and 201b in FIG. 3 is smaller than the width, the horizontal direction, of the second photoelectric conversion units 201a and 201b in FIG. 1.

In the solid-state imaging device 1 illustrated in FIG. 1, the width (area) of the first surfaces and the width (area) of the second surfaces in the light pipes 230a and 230b are equal to each other, the width of the first surfaces and the width of the second surfaces in the light pipes 230a and 230b may be different from each other. In the following, an example of the solid-state imaging device 1B in which the width of the first surfaces and the width of the second surfaces in the light pipes 230a and 230b are different from each other will be described.

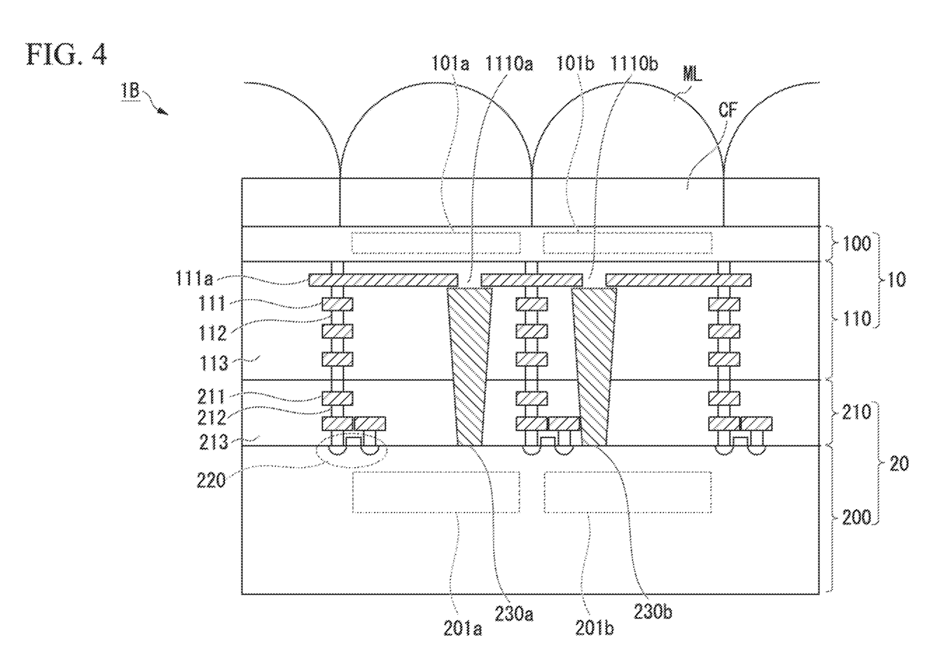

FIG. 4 illustrates another configuration example of the solid-state imaging device 1B according to the present modification example. A section of the solid-state imaging device 1B is illustrated in FIG. 4. The description of the already described portion will be omitted.

In the solid-state imaging device 1B illustrated in FIG. 4, the width of the first surfaces of the light pipes 230a and 230b is greater than the width of the second surfaces thereof. Accordingly, the solid-state imaging device 1B is configured such that the light diffracted by the openings 1110a and 1110b easily enters the light pipes 230a and 230b when passing through the openings 1110a and 1110b.

In the solid-state imaging device 1 illustrated in FIG. 1, the first surfaces of the light pipes 230a and 230b are arranged in the vicinity of the openings 1110a and 1110b. However, the first surfaces of the light pipes 230a and 230b may be away from the openings 1110a and 1110b. In the following, an example of a solid-state imaging device which the first surfaces of the light pipes 230a and 230b are away from the openings 1110a and 1110b will be described.

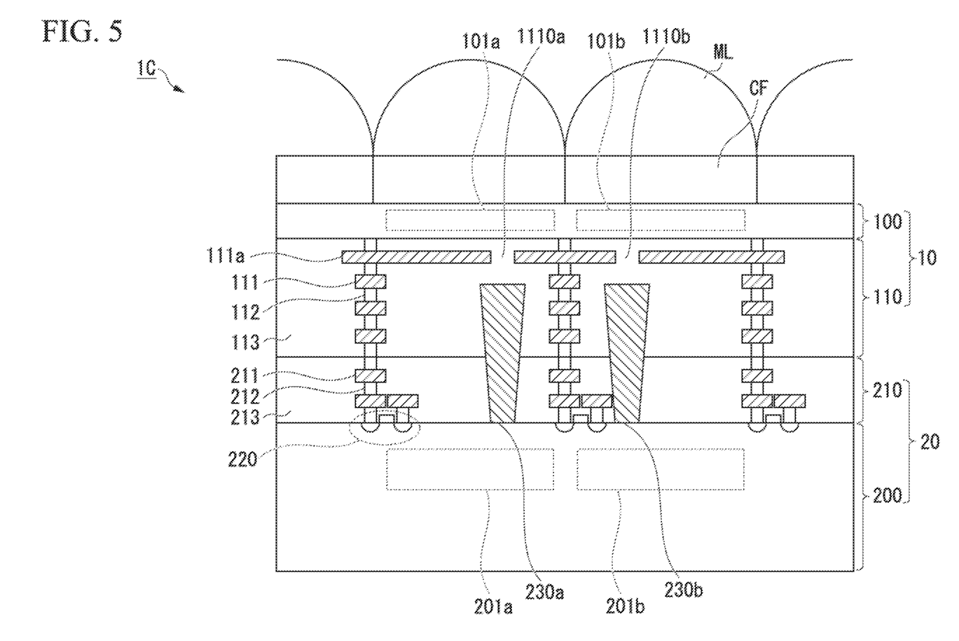

FIG. 5 illustrates another configuration example of a solid-state imaging device 1C according to the present modification example. A section of the solid-state imaging device 1C is illustrated in FIG. 5. The description of the already described portion will be omitted.

In the solid-state imaging device 1C illustrated in FIG. 5, the height of the light pipes 230a and 230b is lower than that the height of the light pipes 230a and 230b in the solid-state imaging device 1 illustrated in FIG. 1. For this reason, in the solid-state imaging device 1C illustrated in FIG. 5, the distance between the light pipes 230a and 230b and the openings 1110a and 1110b is greater than the distance between the light pipes 230a and 230b and the openings 1110a and 1110b in the solid-state imaging device 1 illustrated in FIG. 1.

Additionally, in the solid-state imaging device 1C illustrated in FIG. 5, the width of the first surfaces of the light pipes 230a and 230b is greater than the width of the openings 1110a and 1110b. Moreover, in the solid-state imaging device 1C illustrated in FIG. 5, when viewed from the direction perpendicular to the principal surface of the first substrate 10 or the second substrate 20, that is, when the first substrate 10 or the second substrate 20 is planarly viewed, the opening 1110a is arranged inside the outline (the outline of the first surface of the light pipe 230a) of the light pipe 230a, and the opening 1110b is arranged inside the outline (the outline of the first surface of the light pipe 230b) of the light pipe 230b. Accordingly, the solid-state imaging device 1C is configured such that the light diffracted by the openings 1110a and 1110b easily enters the light pipes 230a and 230b when passing through the openings 1110a and 1110b.

In the solid-state imaging device 1 illustrated in FIG. 1, the first surfaces of the light pipes 230a and 230b are planes. However, curved surfaces may be formed as the first surfaces of the light pipes 230a and 230b. In the following, an example of a solid-state imaging device in which the curved surfaces are formed as the first surfaces of the light pipes 230a and 230b will be described.

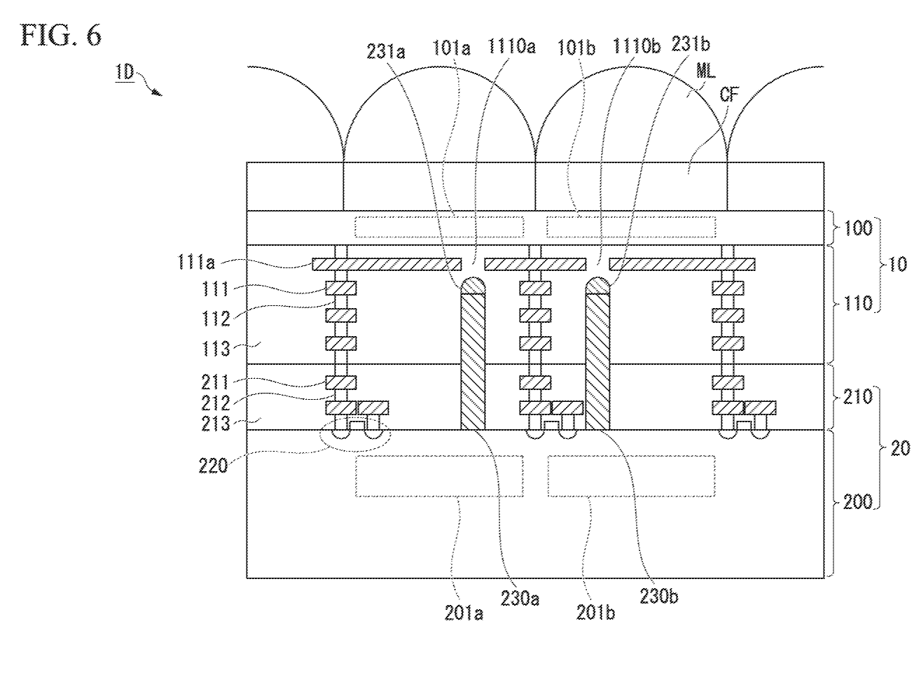

FIG. 6 illustrates another configuration example of a solid-state imaging device 1D according to the present modification example. A section of the solid-state imaging device 1D is illustrated in FIG. 6. The description of the already described portion will be omitted.

In the solid-state imaging device 1D illustrated in FIG. 6, microlenses 231a and 231b are respectively formed in the first surfaces of the light pipes 230a and 230b. The surfaces of the microlenses 231a and 231b have curvature such that the light selected by the light-shielding part 111a, that is, the light passed through the openings 1110a and 1110b is condensed thereon. The light pipes 230a and 230b and the microlenses 231a and 231B function as a refractor that refracts the light, which has entered the surfaces of the microlenses 231a and 231b, to the side of the second photoelectric conversion units 201a and 201b. The quantity of the light that enters the light pipes 230a and 230b increases by forming the microlenses 231a and 231b.

The refractive index of the light pipes 230a and 230b and the refractive index of the microlenses 231a and 231b may be the same or may be different from each other. The same structure as that of the microlenses 231a and 231b may be formed in the light pipes 230a and 230b by machining the first surfaces of the light pipes 230a and 230b in a convex shape.

In the solid-state imaging device 1 illustrated in FIG. 1, the first wiring layer 110 of the first substrate 10 and the second wiring layer 210 of the second substrate 20 are connected together. However, the first wiring layer 110 of the first substrate 10 and the second semiconductor layer 200 of the second substrate 20 may be connected together. In the following, an example of a solid-state imaging device in which the first wiring layer 110 of the first substrate 10 and the second semiconductor layer 200 of the second substrate 20 are connected together will be described.

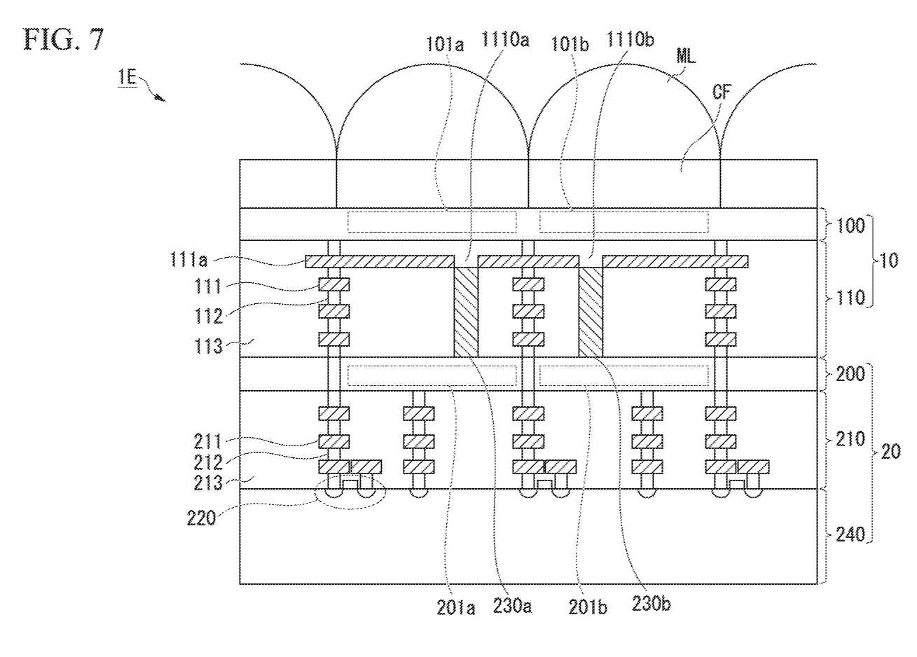

FIG. 7 illustrates another configuration example of a solid-state imaging device 1E according to the present modification example. A section of the solid-state imaging device 1E is illustrated in FIG. 7. The description of the already described portion will be omitted.

In the solid-state imaging device 1E illustrated in FIG. 7, the second substrate 20 has the second semiconductor layer 200, the second wiring layer 210, and a third semiconductor layer 240. In the solid-state imaging device 1 illustrated in FIG. 1, the first substrate 10 and the second substrate 20 are connected together in a state in which the first wiring layer 110 of the first substrate 10 and the second wiring layer 210 of the second substrate 20 face each other. However, in the solid-state imaging device 1E illustrated in FIG. 7, the first substrate 10 and the second substrate 20 are connected together in a state in which the first wiring layer 110 of the first substrate 10 and the second semiconductor layer 200 of the second substrate 20 face each other.

The second semiconductor layer 200 and the second wiring layer 210 overlap each other in the direction (for example, the direction substantially perpendicular to the principal surface of the second substrate 20) crossing the principal surface of the second substrate 20. Additionally, the second semiconductor layer 200 and the second wiring layer 210 are in contact with each other.

The second wiring layer 210 and the third semiconductor layer 240 overlap each other in the direction (for example, the direction substantially perpendicular to the principal surface of the second substrate 20) crossing the principal surface of the second substrate 20. Additionally, the second wiring layer 210 and the third semiconductor layer 240 are in contact with each other.

The second semiconductor layer 200 has a first surface that is in contact with the second wiring layer 210, and a second surface that is in contact with the first wiring layer 110 and is opposite to the first surface of the opposite side. The second surface of the second semiconductor layer 200 constitutes one of the principal surfaces of the second substrate 20.

The second wiring layer 210 has a first surface that is in contact with the third semiconductor layer 240, and a second surface that is in contact with the second semiconductor layer 200 and is opposite to the first surface. The third semiconductor layer 240 has a first surface, and a second surface that is in contact with the second wiring layer 210 and is opposite to the first surface. The first surface of the third semiconductor layer 240 constitutes one of the principal surfaces of the second substrate 20. The source region and the drain region of the MOS transistor 220 are formed in the third semiconductor layer 240.

The first vias 112 of the first wiring layer 110, and the second vias 212 that have passed through the second semiconductor layer 200 from the second wiring layer 210 are electrically connected together in the interface between the first substrate 10 and the second substrate 20. Additionally, the second surfaces of the light pipes 230a and 230b are in contact with the second surface of the second semiconductor layer 200.

In addition, in the solid-state imaging device 1E, the first surfaces of the light pipes 230a and 230b are in contact with the light-shielding part 111a, but may not be in contact with the light-shielding part 111a like the solid-state imaging device 1 of FIG. 1.

Even in the solid-state imaging device 1F illustrated in FIG. 7, a major portion of the light, which has entered the first surfaces of the light pipes 230a and 230b, can be guided to the second photoelectric conversion units 201a and 201b by the light pipes 230a and 230b.

### Second Embodiment

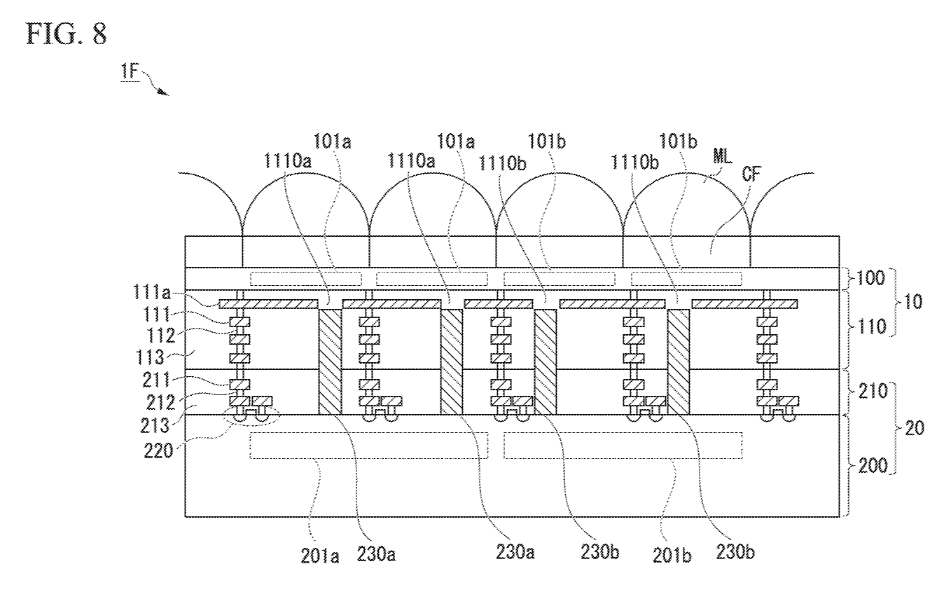

Next, a second embodiment of the invention will be described. FIG. 8 illustrates a configuration example of a solid state imaging device 1F according to the present embodiment. A section of the solid-state imaging device 1F is illustrated in FIG. 8. The description of the already described portion will be omitted.

In the solid-state imaging device 1 according to the first embodiment, the second photoelectric conversion units 201a and 201b are formed in a one-one relationship with the first photoelectric conversion units 101a and 101b, whereas in the solid-state imaging device 1F according to the second embodiment, one second photoelectric conversion unit 201a or 201b is formed for two first photoelectric conversion units 101a or 101b. In other words, in the solid-state imaging device 1 according to the first embodiment, the number of the first photoelectric conversion units 101a and 101b and the number of the second photoelectric conversion units 201a and 201b are the same and the light transmitted through only one first photoelectric conversion units 101a or 101b enters one second photoelectric conversion units 201a or 201b. In contrast, in the solid-state imaging device 1F according to the second embodiment, the number of the first photoelectric conversion units 101a and 101b is twice greater the number of the second photoelectric conversion units 201a and 201b, and the light transmitted through the two first photoelectric conversion units 101a or 101b enters one second photoelectric conversion unit 201a or 201b.

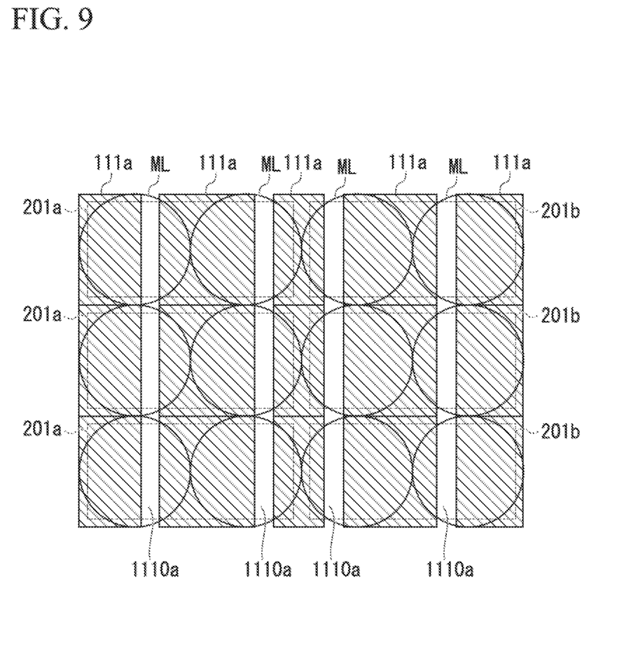

FIG. 9 illustrates a state in which the solid-state imaging device 1F illustrated in FIG. 8 is planarly viewed. A state in which the solid-state imaging device 1F is viewed from the principal surface side of the second substrate 20 connected to the first substrate 10 is illustrated in FIG. 9.

The second photoelectric conversion units 201a and 201b are arranged in a two-dimensional matrix. Two microlens ML are arranged to correspond to one second photoelectric conversion unit 201a or 201b. Although the first photoelectric conversion units 101a and 101b are omitted in FIG. 9, two first photoelectric conversion units 101a or 101b are arranged to corresponding to one second photoelectric conversion unit 201a or 201b. When viewed from the direction perpendicular to the principal surface of the first substrate 10 or the second substrate 20, that is, when the first substrate 10 or the second substrate 20 is planarly viewed, a plurality of units among a plurality of first photoelectric conversion units 101a or 101b overlap each of a plurality of second photoelectric conversion units 201a or 201b. In the present embodiment, two first photoelectric conversion units 101a overlap one second photoelectric conversion unit 201a, and two first photoelectric conversion units 101b overlap one second photoelectric conversion unit 201b.

Oblong openings 1110a arranged so as to be biased to the right side with respect to the second photoelectric conversion unit 201a are formed at positions that overlap the second photoelectric conversion unit 201a. Oblong openings 1110b biased to the left side with respect to the second photoelectric conversion unit 201b are formed at positions that overlap the second photoelectric conversion unit 201b.

The openings 1110a and the openings 1110b are arranged so that the planar positions thereof within the respective pixels become bilaterally symmetrical. Therefore, the light, which has passed through the left and right pupil regions, which are biased in leftward and rightward directions that are directions opposite to each other in the exit pupil of the imaging lens, respectively, is received in the second photoelectric conversion unit 201a and the second photoelectric conversion unit 201b.

The light transmitted through the two first photoelectric conversion units 101a and passed through the light pipe 230a enters one second photoelectric conversion unit 201a. Additionally, the light transmitted through the two first photoelectric conversion units 101b and passed through the light pipe 230b enters one second photoelectric conversion unit 201b.

For this reason, in the present embodiment, the quantity of the light that enters the second photoelectric conversion units 201a and 201b increases as compared to the first embodiment. Therefore, the S/N ratio of signals generated by the second photoelectric conversion units 201a and 201b increases.

### Third Embodiment

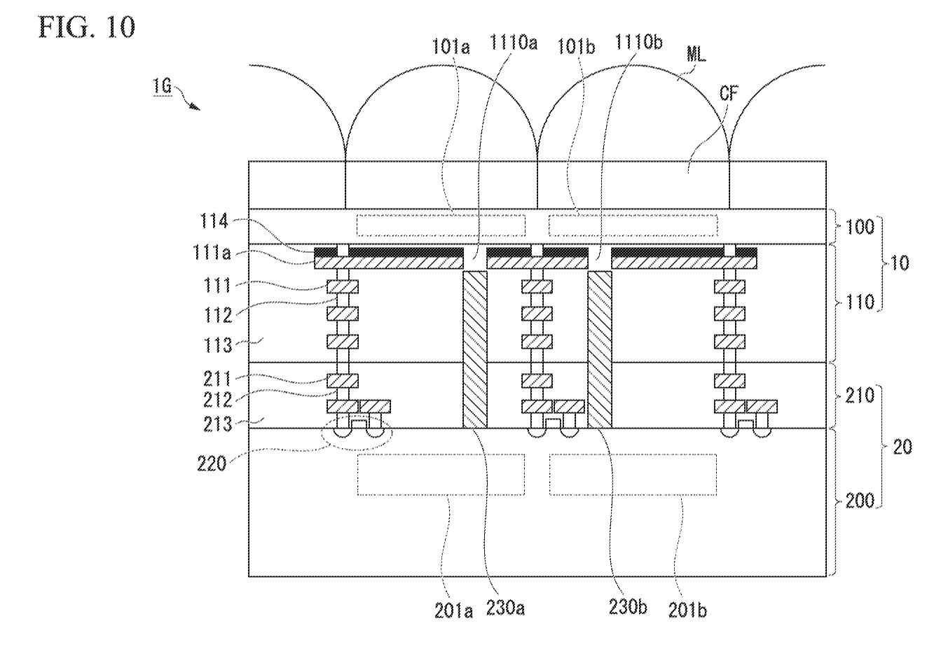

Next, a third embodiment of the invention will be described. FIG. 10 illustrates a configuration example of a solid state imaging device 1G according to the present embodiment. A section of the solid-state imaging device 1G is illustrated in FIG. 10. The description of the already described portion will be omitted.

An optical absorber 114, which absorbs light other than the light that has passed through only one of the two pupil regions in the exit pupil of the imaging lens in the light transmitted through the first photoelectric conversion units 101a and 101b, is arranged in regions other than regions where the openings 1110a and 1110b are formed, in a surface that faces the first photoelectric conversion units 101a and 101b, out of two surfaces of the light-shielding part 111a formed as a thin film. In other words, the optical absorber 114 suppresses reflection of light other than the light that has passed through only one of the two pupil regions in the exit pupil of the imaging lens in the light transmitted through the first photoelectric conversion units 101a and 101b. The optical absorber 114 is formed as a thin film and is in contact with the light-shielding part 111a.

The optical absorber 114 absorbs visible light. For example, the optical absorber 114 is formed as a dielectric multilayer film in which one or more layers of dielectrics with a low refractive index and one or more layers of dielectrics with a high refractive index are laminated. The optical absorber 114 may be made of only one layer of dielectrics.

The light-shielding part 111a is made of metals, such as aluminum or copper, and has high reflective properties in a visible light region. In the first embodiment, the optical absorber is not provided on an upper surface of the light-shielding part 111a. Therefore, multiple reflection may occur when the light reflected by the surface of the light-shielding part 111a is reflected by an interface between the first wiring layer 110 and the first semiconductor layer 100, an interface between the first semiconductor layer 100 and the first color filter Cf, or the like.

Originally, the second photoelectric conversion unit 201a formed at a position corresponding to the opening 1110a receives the light that has passed through the left pupil region in the exit pupil of the imaging lens. However, the light, which has been reflected by the surface of the light-shielding part 111a and multi-reflected as described above, may enter the light pipe 230a and enter the second photoelectric conversion unit 201a. That is, there is a concern that the second photoelectric conversion unit 201a may receive the light that has passed through the right pupil region in the exit pupil of the imaging lens. The same applies to the second photoelectric conversion unit 201b formed at a position corresponding to the opening 1110b.

In the present embodiment, the light-shielding part 111a can be made to absorb the light causing the multiple reflection by providing the optical absorber 114 absorbing visible light in the surface of the light-shielding part 111a that faces the first photoelectric conversion units 101a and 101b. Accordingly, the solid-state imaging device 1G is configured such that the light, which has passed through only one of the two pupil regions in the exit pupil of the imaging lens, easily enters the light pipes 230a and 230b.

Therefore, the second photoelectric conversion units 201a and 201b easily receive the light that has passed only one of the two pupil regions in the exit pupil of the imaging lens, and do not easily receive the other light. Accordingly, a focal point can be precisely detected using signals for focus detection based on the second signals generated by the second photoelectric conversion units 201a and 201b.

### Fourth Embodiment

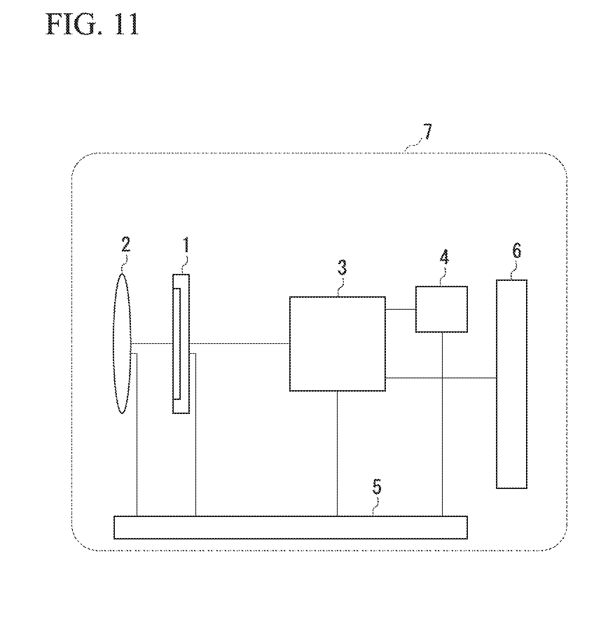

Next, a fourth embodiment of the invention will be described. In the present embodiment, an imaging apparatus in which the solid-state imaging device 1, 1A, 1B, 1C, 1D, 1E, 1F, or 1G according to any of the first embodiment, the second embodiment, and the third embodiment (including the modification examples) is mounted will be described. FIG. 11 illustrates a configuration example of an imaging apparatus on which the solid-state imaging device 1 of the first embodiment is mounted. The imaging apparatus according to the present embodiment just has to be electronic apparatuses having an imaging function, and may be digital camcorders, endoscopes, or the like besides digital cameras.

The imaging device 7 illustrated in FIG. 11 has the solid-state imaging device 1 a lens unit section 2, an image signal processing device 3, a recording device 4, a camera control device 5, and a display device 6.

In the lens unit section 2, driving of zooming, focusing, diaphragming, and the like are controlled by the camera control device 5, and an image of light from a subject is formed on the solid-state imaging device 1. The solid-state imaging device 1 has its driving controlled by the camera control device 5, converts the light, which has entered the solid-state imaging device 1, via the lens unit section 2 into electrical signals, and outputs imaging signals and signals for focus detection according to the amount of the light that has entered to the image signal processing device 3.

The image signal processing device 3 processes signal amplification, conversion into image data, and various kinds of correction, and then, processing such compression of the image data, on the imaging signals input from the solid-state imaging device 1. Additionally, the image signal processing device 3 calculates a focal point, using the signals for focus detection input from the solid-state imaging device 1. The solid-state imaging device 1 may calculate the focal point. The image signal processing device 3 uses a memory (not illustrated) as temporary storage means for image data and the like in each processing.

The recording device 4 is a detachable recording medium, such as a semiconductor memory and performs recording or reading of image data. The display device 6 is a display device, such as liquid crystal, which displays an image based on the image data processed by the image signal processing device 3 or the image data read from the recording device 4. The camera control device 5 is a control device that controls the overall imaging device 7.

According to the present embodiment, the imaging device 7 characterized by including the solid-state imaging device 1 according to any of the first embodiment, the second embodiment, and the third embodiment is configured.

In the present embodiment, a decrease in the quantity of the light that enters the second photoelectric conversion units 201a and 201b that generate signals for focus detection using the phase difference detection method can be suppressed while suppressing degradation in the sensitivity of the first photoelectric conversion units 101a and 101b that generate signals for imaging signals. Therefore, degradation in the detection precision of a focal point can be suppressed while suppressing degradation in the resolution of imaging signals.

Although the embodiments of the invention has been described above in detail with reference to the drawings, specific configuration is not limited to the above embodiments, and design changes and the like are also included without departing from the scope of the invention.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. A solid-state imaging device comprising:
a first substrate having a plurality of first photoelectric conversion units arranged in two dimensions;
a second substrate having a plurality of second photoelectric conversion units arranged in two dimensions and being stacked on the first substrate;
a microlens arranged on a surface of the first substrate to form an image of light that has passed through an imaging lens;
a selector arranged between the first photoelectric conversion units and the second photoelectric conversion units to select light that has passed through only one of two pupil regions in an exit pupil of the imaging lens in light passed through the microlens and transmitted through the first photoelectric conversion units;
a refractor arranged between the selector and the second photoelectric conversion units to refract the light selected by the selector to a side of the second photoelectric conversion units;
a first wiring arranged on the first substrate to transmit signals for imaging signals generated by the plurality of first photoelectric conversion units; and
a second wiring arranged on the second substrate to transmit signals for focus detection using a phase difference detection method, which are generated by the plurality of second photoelectric conversion units.

2. The solid-state imaging device according to claim 1, further comprising:
an interlayer insulator arranged between the first photoelectric conversion units and the second photoelectric conversion units,
wherein the refractor is embedded in the interlayer insulator, and is formed of a material having a higher refractive index than that of the interlayer insulator.

3. The solid-state imaging device according to claim 2,
wherein the refractor is a light pipe that totally reflects light refracted to the side of the second photoelectric conversion units and guides the light to the second photoelectric conversion units.

4. The solid-state imaging device according to claim 1,
wherein the selector includes a light-shielding part having openings formed at positions through which the light that has passed through only one of the two pupil regions of the imaging lens passes.

5. The solid-state imaging device according to claim 4,
wherein a surface of the refractor that faces the first photoelectric conversion units is arranged in vicinity of the openings.

6. The solid-state imaging device according to claim 4,
wherein the openings are arranged inside an outline of the refractor when viewed from a direction perpendicular to a principal surface of the first substrate or the second substrate.

7. The solid-state imaging device according to claim 4,
wherein an optical absorber, which absorbs light other than the light that has passed through only one of the two pupil regions in the exit pupil of the imaging lens in the light transmitted through the first photoelectric conversion units, is arranged in regions other than regions where the openings are formed, in a surface of the selector that faces the first photoelectric conversion units.

8. The solid-state imaging device according to claim 1,
wherein a surface of the refractor that faces the first photoelectric conversion units has a curvature such that the light selected by the selector is condensed.

9. The solid-state imaging device according to claim 1,
wherein a plurality of units among the plurality of first photoelectric conversion units overlap each of the plurality of second photoelectric conversion units when viewed from a direction perpendicular to a principal surface of the first substrate or the second substrate.

10. An imaging apparatus comprising:
the solid-state imaging device according to claim 1.
